(19) United States
(12) Patent Application Publication
(10) Pub. No.: US 2019/0206718 A1
(43) Pub. Date: Jul. 4, 2019

(54) BACK-END-OF-LINE STRUCTURES WITH AIR GAPS

(71) Applicant: GLOBALFOUNDRIES Inc., Grand Cayman (KY)

(72) Inventors: Nicholas V. LiCausi, Watervliet, NY (US); Shao Beng Law, Watervliet, NY (US); Sunil K. Singh, Mechanicville, NY (US); Xunyuan Zhang, Troy, NY (US)

(21) Appl. No.: 15/860,121

(22) Filed: Jan. 2, 2018

(51) Int. Cl. H01L 21/768; H01L 23/528; H01L 23/532; H01L 21/311; H01L 21/3105; H01L 21/02

(52) U.S. Cl. CPC H01L 21/7682; H01L 23/528; H01L 23/53295; H01L 21/76816; H01L 2221/1047; H01L 21/31111; H01L 21/31058; H01L 21/02118; H01L 21/02274; H01L 21/76828

(57) ABSTRACT

Interconnect structures and methods for forming an interconnect structure. First and second metallization structures are formed in an intralayer dielectric layer. The intralayer dielectric layer is removed to form a cavity with an entrance between the first and second metallization structures. A dielectric layer is deposited on surfaces surrounding the cavity, over the first metallization structure, and over the second metallization structure. A sacrificial material is formed inside the cavity after the dielectric layer is deposited. A cap layer is deposited on the dielectric layer over the first metallization structure, the dielectric layer over the second metallization structure, and the sacrificial material inside the cavity to close the entrance to the cavity. After the cap layer is deposited, the sacrificial material is removed from the cavity. The dielectric layer and cap layer cooperate to encapsulate an air gap inside the cavity.

### BACKGROUND

The present invention relates to semiconductor device fabrication and integrated circuits and, more specifically, to interconnect structures and methods for forming an interconnect structure.

An interconnect structure may be used to electrically connect device structures fabricated by front-end-of-line (FEOL) processing. A back-end-of-line (BEOL) portion of the interconnect structure may include metallization formed using a damascene process in which via openings and trenches etching in a dielectric layer are filled with metal to create features of a metallization level. The dielectric layer may be formed from low-k dielectric materials that provide a reduced capacitance, but such reduced-capacitance dielectric layers are also required to provide a high level of performance.

Improved interconnect structures and methods for forming an interconnect structure are needed.

### SUMMARY

In an embodiment of the invention, an interconnect structure includes a metallization level including a first metallization structure, a second metallization structure, and a first cavity with an entrance arranged between the first metallization structure and the second metallization structure. A cap layer is located over the metallization level, and is arranged relative to the first metallization structure and the second metallization structure to close the entrance to the cavity. A dielectric layer is arranged on surfaces surrounding the cavity, between the cap layer and the first metallization structure, and between the cap layer and the second metallization structure. The dielectric layer and cap layer encapsulate an air gap inside the cavity.

In an embodiment of the invention, a method includes forming a first metallization structure and a second metallization structure in an intralayer dielectric layer, and removing the intralayer dielectric layer to form a cavity with an entrance between the first metallization structure and the second metallization structure. The method further includes depositing a dielectric layer on surfaces surrounding the cavity, over the first metallization structure, and over the second metallization structure, and forming a sacrificial material inside the cavity after the dielectric layer is deposited. The method further includes depositing a cap layer on the dielectric layer over the first metallization structure, on the dielectric layer over the second metallization structure, and on the sacrificial material to close the entrance to the cavity. After the cap layer is deposited, the sacrificial material is removed from the cavity. The dielectric layer and cap layer encapsulate an air gap inside the cavity.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-6 are cross-sectional views of a structure at successive fabrication stages of a processing method in accordance with embodiments of the invention.

FIG. 1A is a top view of the structure of FIG. 1 in which FIG. 1 is taken generally along line 1-1.

### DETAILED DESCRIPTION

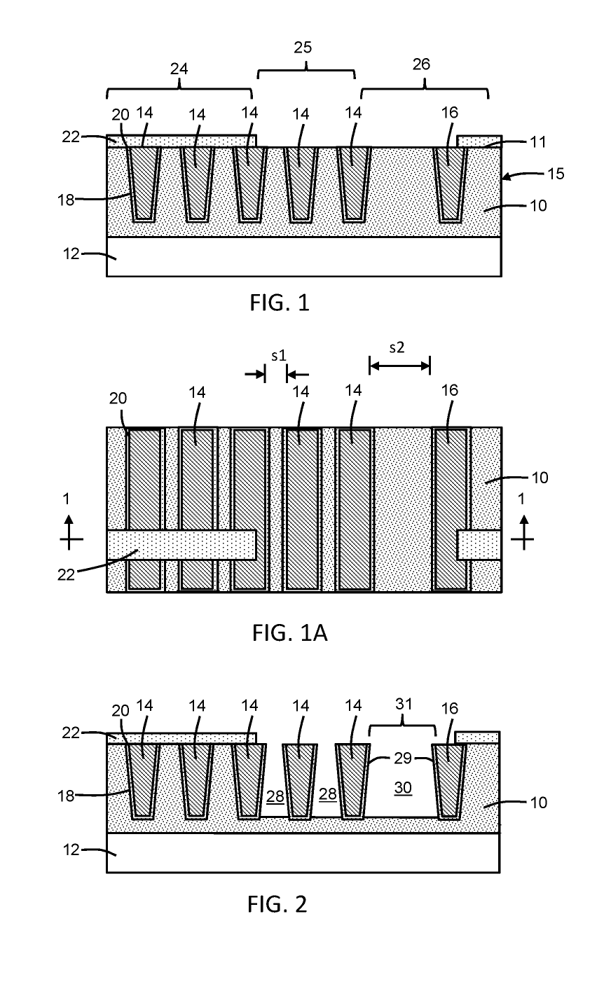

With reference to FIGS. 1, 1A and in accordance with embodiments of the invention, a metallization level 15 includes an intralayer dielectric layer 10 arranged on a substrate 12 and metallization structures 14, 16 are formed in openings 18 that are defined in the intralayer dielectric layer 10. The intralayer dielectric layer 10 may be composed of an electrical insulator, such as a low-k dielectric material or an ultra-low-k (ULK) dielectric material. The substrate 12 may include device structures formed by front-end-of-line (FEOL) processes in a semiconductor layer, as well as one or more metallization levels formed by middle-of-line (MOL) processing or by back-end-of-line (BEOL) processing.

The openings 18 in the intralayer dielectric layer 10 may be formed by lithography and etching at selected locations distributed across the surface area of intralayer dielectric layer 10. The openings 18 may be contact openings, via openings, or trenches and, in that regard, may have an aspect ratio of height-to-width that is characteristic of a contact opening, a via opening, or a trench. In an embodiment, the openings 18 may be trenches that are formed in the intralayer dielectric layer 10.

The interior surfaces surrounding each of the openings 18 may be coated with a liner layer 20 of a given conformal thickness. The liner layer 20 may be composed of one or more conductive materials (i.e., conductors), such as titanium nitride (TiN), tantalum nitride (TaN), tantalum (Ta), titanium (Ti), tungsten (W), tungsten nitride (WN), ruthenium (Ru), rhenium (Re), a layered stack of these conductive materials (e.g., a bilayer of Ti and TiN), or a combination of these conductive materials, deposited by, for example, physical vapor deposition (PVD) or chemical vapor deposition (CVD). The metallization structures 14, 16 may be sections of a conductor layer that is deposited in the openings 18 after the liner layer 20. The conductor layer may be composed of a metal, such as copper (Cu), cobalt (Co), ruthenium (Ru), or rhenium (Re) that is deposited by electroless or electrolytic deposition. The respective materials of the liner layer 20 and the conductor layer also deposit in the field area on the top surface 11 of the intralayer dielectric layer 10, and may be removed from the field area with a chemical mechanical polishing (CMP) process.

A hardmask layer 22 is deposited and patterned to define a block mask covering an area of the intralayer dielectric layer 10 in a defined region 24 in which the metallization structures 14 will be subsequently contacted from above by vias in an overlying metallization level and air gaps are undesired. The hardmask layer 22 may be composed of a dielectric material, such as silicon nitride (Si₃N₄), deposited by chemical vapor deposition (CVD), and may be patterned with a lithography and etching process selective to the material of the intralayer dielectric layer 10. As used herein, the term “selective” in reference to a material removal process (e.g., etching) denotes that the material removal rate (i.e., etch rate) for the targeted material is higher than the material removal rate (i.e., etch rate) for at least another material exposed to the material removal process.

Regions 25 and 26 of the intralayer dielectric layer 10 are not masked by the hardmask layer 22, and may represent respective regions in which air gaps to be formed. In regions 24 and 25, the metallization structures 14 are separated from each other by a spacing, s1. In region 26, the metallization structure 16 is separated from the nearest metallization structure 14 by a spacing, s2, that is greater than the spacing, s1, in regions 24 and 25. In conventional air gap formation processes, the region 26 is also masked by a block mask because of the inability to form closed air gaps with pinchoff because of the wide spacing in region 26.

With reference to FIG. 2 in which like reference numerals refer to like features in FIG. 1 and at a subsequent fabrication stage, the intralayer dielectric layer 10 is at least partially removed in regions 25 and 26 over areas that are not masked by the hardmask layer 22, which forms openings or cavities 28 between adjacent metallization structures 14 and forms an opening or cavity 30 between the metallization structure 16 and the metallization structure 14 that is closest or nearest to the metallization structure 16. The unmasked dielectric material of the intralayer dielectric layer 10 is removed selective to the materials of the metallization structures 14, 16 and the liner layer 20. The intralayer dielectric layer 10 between adjacent metallization structures 14 is retained in region 24 over the area masked by the hardmask layer 22.

In an embodiment, the unmasked material of the intralayer dielectric layer 10 in regions 25 and 26 may be damaged and removed, along with the hardmask layer 22, by an etching process, such as wet chemical etching using a solution of dilute hydrofluoric acid (dHF). For example, the unmasked material of the intralayer dielectric layer 10 may be damaged by exposure to radicals (i.e., uncharged or neutral species) generated from a gas mixture of nitrogen (N₂) and hydrogen (H₂) in a remote plasma.

The height of the cavities 28, 30 may extend in a vertical direction over the full height of the metallization structures 14, 16 to terminate near the respective bottom surfaces of the metallization structures 14, 16. Each of the cavities 28 extends horizontally from the liner layer 20 on one of the metallization structures 14 to the liner layer 20 on another of the metallization structures 14. The cavity 30 is partially surrounded by surfaces 29 and includes an entrance 31 that allows access to the space that is partially surrounded by the surfaces 29. The cavity 30 extends horizontally from a surface 29 of the liner layer 20 at the sidewall of one of the metallization structures 14 to a surface 29 of the liner layer 20 at the sidewall of the metallization structure 16. The volume of the cavities 28 is less than the volume of the cavity 30 and, in particular, the width at the entrance 31 to the cavity 30 is greater than the width at the respective entrances to the cavities 28.

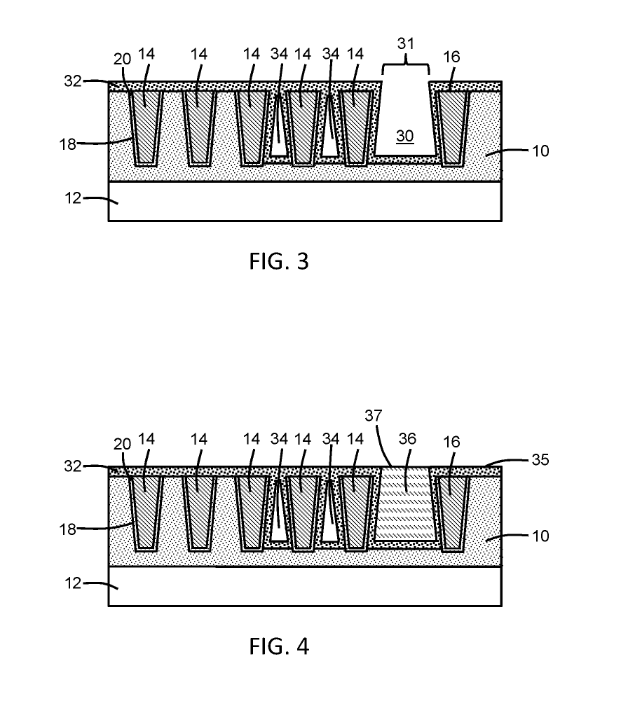

With reference to FIG. 3 in which like reference numerals refer to like features in FIG. 2 and at a subsequent fabrication stage, the hardmask layer 22 is removed to expose region 24, and a dielectric layer 32 is deposited with a given thickness over the structure. The dielectric layer 32 may be conformal and may be composed of a dielectric material or a low-k dielectric material, such as silicon nitride (SiNx), silicon dioxide (SiO₂), silicon-carbon-oxy-nitride (SiCON), or silicon-carbon nitride (SiCN). The dielectric layer 32 coats the surfaces inside each of the smaller cavities 28 and pinches off at their respective entrances, during deposition, to form air gaps 34 that are encapsulated (i.e., completely surrounded) by the dielectric layer 32. To that end, the entrance to each cavity 28 is closed before the cavity volume can be filled by the depositing dielectric material.

The cavity 30 does not support pinch off because of its relatively large dimensions (e.g., width) at its entrance 31 in comparison with the entrances to the cavities 28. Instead, the dielectric layer 32 deposits on the surfaces 29 of the cavity 30 and partially surrounds the cavity 30 such that the volume of the cavity 30 is reduced. The dielectric layer 32 narrows the dimensions of the cavity 30, particularly the width of the cavity 30 at its entrance 31, such that the cavity 30 is only partially surrounded by the dielectric layer 32.

With reference to FIG. 4 in which like reference numerals refer to like features in FIG. 3 and at a subsequent fabrication stage, a sacrificial layer 36 is applied that fills the space inside cavity 30 (FIG. 3) that is not filled by the dielectric layer 32. The sacrificial layer 36 may be composed of an energy removal film material and, in an embodiment, may be composed of an organic (CxHyOz) compound, such as a silicon-based organic compound that is deposited by, for example, plasma-enhanced chemical vapor deposition (PE-CVD) or a spin-on process. In an embodiment, the energy removal film material constituting the sacrificial layer 36 may be comprised of a porogen material, which is a sacrificial organic-based material that is converted from a solid state to a gaseous state when treated with heat energy and/or electromagnetic energy. The sacrificial layer 36 in cavity 30 may be etched back following formation to have a top surface 37 that is coplanar with a top surface 35 of the dielectric layer 32.

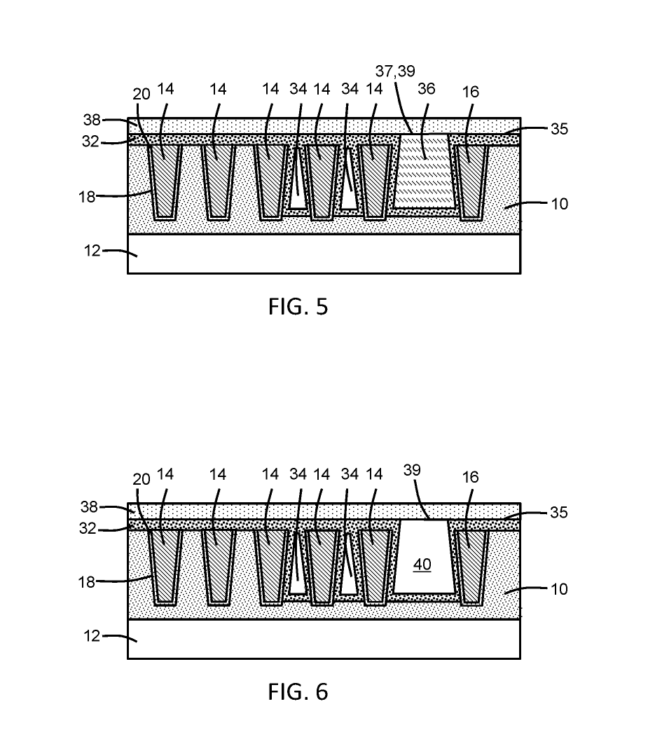

With reference to FIG. 5 in which like reference numerals refer to like features in FIG. 4 and at a subsequent fabrication stage, a cap layer 38 is formed over the structure and closes the entrance 31 to cavity 30 (FIG. 3). In particular, a section of the cap layer 38 is arranged on the sacrificial layer 36 located inside cavity 30 (FIG. 3) and on the top surface 35 of the dielectric layer 32. The cap layer 38 has a bottom surface 39 that bridges across the top surface 37 of the sacrificial layer 36 and that is coplanar with the top surface 37 of the sacrificial layer 36 along the interface between the surfaces 37 and 39. The bottom surface 39 of the cap layer 38 is planar, and the top surface of the cap layer 38 opposite to the bottom surface 39 is also planar. The sacrificial layer 36 blocks the deposition of the cap layer 38 inside the cavity 30 and provides a surface 37 that supports the cap layer 38 deposits. The sacrificial layer constrains the cap layer 38 to bridge across the entrance 31 to the cavity 30 with planar top and bottom surfaces, and prohibits the occurrence of a pinched-off, non-planar shape adjacent to the entrance 31 to the cavity 30.

In an embodiment, the cap layer 38 may be composed of a dielectric material, such as silicon nitride (Si₃N₄), containing a concentration of a porogen that is activated by curing to form pores in a solid matrix. The pores may be connected to provide pathways for gaseous diffusion through the solid matrix, such as the products of the curing process. The porogen is a sacrificial organic-based material in the form of particles that are distributed in the matrix of the cap layer 38 and that are used to generate or form pores when the cap layer 38 is cured. The porosity of the cap layer 38, following curing, may be adjusted by adjusting the concentration of porogen in the matrix. In an alternative embodiment, the cap layer 38 may be composed of a dielectric material, such as silicon nitride (Si₃N₄), with less than full density than normal density content as may occur with a hydrogen-rich deposition.

With reference to FIG. 6 in which like reference numerals refer to like features in FIG. 5 and at a subsequent fabrication stage, the sacrificial layer 36 (FIG. 5) is removed by an activation treatment to form an air gap 40 inside the cavity 30 (FIG. 3). In an embodiment, the activation treatment may cause the material of the sacrificial layer 36 to decompose from a solid state into a gaseous state, and the resultant vapor or gas may be released to the ambient environment through the porous dielectric material of the cap layer 38. In an embodiment in which the sacrificial layer 36 is composed of an energy removal film material, the thermal treatment of the energy removal film material may heat the energy removal film to a temperature in a range of 100° C. to 600° C. for a given time (i.e., longer times for lower temperatures). In an embodiment, the thermal treatment of the energy removal film material may be combined with exposure to electromagnetic energy, such as exposure to ultraviolet (UV) radiation. For example, the thermal treatment may heat the energy removal film material to a temperature of 400° C. and may include continuous or intermittent exposure to ultraviolet radiation during heating.

In an embodiment in which the sacrificial layer 36 is completely removed, the air gap 40 may occupy the entire space formerly occupied by the sacrificial layer 36. The air gap 40 is arranged laterally between the metallization structure 16 and the nearest metallization structure 14 with sections of the dielectric layer 32 arranged as intervening structures. The cap layer 38 is not modified by the removal of the sacrificial layer 36. The cap layer 38 and dielectric layer 32 cooperate to completely surround the air gap 40 with the cap layer 38 extending across the entrance 31 of the cavity 30 (FIG. 3) to close the air gap 40. The air gap 40 extends vertically through the dielectric layer 32 such that a portion of the air gap 40 is not located inside the cavity 30 but is instead arranged above the cavity 30. The air gaps 34 are smaller in volume than the air gap 40, and the air gap 40 is separated from the nearest air gap 34 by the metallization structure 14 that is nearest to metallization structure 16. The depths of the cavities 28 and the depth of the cavity 30 are selected to promote the lateral separation between the air gaps 34, 40, and are equal in the representative embodiment. The air gap 40 may be formed independent of ground rule limitations due at least in part to the temporary presence of the sacrificial layer 36 to provide a support structure that promotes the ability of the cap layer 38 to deposit and close the air gap 40.

The air gap 40 may be characterized by a permittivity or dielectric constant of near unity (i.e., vacuum permittivity). The air gap 40 may be filled by atmospheric air at or near atmospheric pressure, may be filled by another gas (e.g., the gas resulting from the decomposition of the energy removal film) at or near atmospheric pressure, or may contain atmospheric air or another gas at a sub-atmospheric pressure (e.g., a partial vacuum).

In an embodiment in which the cap layer 38 contains a porogen concentration when deposited, the curing of the dielectric material of the cap layer 38 to convert its porogen concentration to pores and to provide its porosity may cause the sacrificial layer 36 to decompose into its gaseous state, which may be released to the ambient environment through the pores generated in the cap layer 38 during its curing.

The BEOL processing may continue to form additional metallization levels over the cap layer 38. In an embodiment, the metallization structures 14, 16 and the air gaps 34, 40 may be arranged in the lowest or first BEOL metallization level that is stacked closest to the FEOL device structures.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An interconnect structure comprising:
a metallization level including a first metallization structure, a second metallization structure, and a first cavity with an entrance arranged between the first metallization structure and the second metallization structure;
a cap layer over the metallization level, the cap layer arranged relative to the first metallization structure and the second metallization structure to close the entrance to the first cavity; and
a dielectric layer arranged on surfaces surrounding the first cavity, between the cap layer and the first metallization structure, and between the cap layer and the second metallization structure,
wherein the dielectric layer and the cap layer encapsulate a first air gap inside the first cavity, the cap layer has a planar bottom surface arranged over the first cavity that closes the first cavity, and the first air gap extends vertically through a break in the dielectric layer at the entrance to the first cavity and terminates at the planar bottom surface of the cap layer.

2. The interconnect structure of claim 1 wherein the metallization level includes a third metallization structure and a second cavity arranged between the second metallization structure and the third metallization structure, and the dielectric layer is further arranged to completely surround the second cavity and define a second air gap.

3. The interconnect structure of claim 2 wherein the first metallization structure is spaced from the second metallization structure by a first spacing, and the second metallization structure is spaced from the third metallization structure by a second spacing that is less than the first spacing.

4. The interconnect structure of claim 3 wherein the second spacing is selected with a dimension that provides pinch off of the dielectric layer at an entrance to the second cavity.

5. The interconnect structure of claim 2 wherein the first air gap has a first volume, and the second air gap has a second volume that is less than the first volume.

6. The interconnect structure of claim 1 wherein the surfaces surrounding the first cavity include a first liner layer at a sidewall of the first metallization structure and a second liner layer at a sidewall of the second metallization structure.

7. The interconnect structure of claim 1 wherein the cap layer is composed of a porous dielectric material.

8. (canceled)

9. The interconnect structure of claim 1 wherein the first metallization structure and the second metallization structure have a parallel arrangement, and the first metallization structure and the second metallization structure are composed of a conductor.

10. A method comprising:
forming a metallization level including a first metallization structure and a second metallization structure in an intralayer dielectric layer;
removing the intralayer dielectric layer to form a first cavity with an entrance between the first metallization structure and the second metallization structure;
depositing a dielectric layer on surfaces surrounding the first cavity, over the first metallization structure, and over the second metallization structure;
after the dielectric layer is deposited, forming a sacrificial material inside the first cavity;
depositing a cap layer on the dielectric layer over the first metallization structure, the dielectric layer over the second metallization structure, and the sacrificial material inside the first cavity to close the entrance to the first cavity; and
after the cap layer is deposited, removing the sacrificial material from the first cavity,
wherein the dielectric layer and the cap layer encapsulate a first air gap inside the first cavity, the cap layer has a planar bottom surface arranged over the first cavity that closes the first cavity, and the first air gap extends vertically through a break in the dielectric layer at the entrance to the first cavity and terminates at the planar bottom surface of the cap layer.

11. The method of claim 10 wherein the sacrificial material is an energy removal film.

12. The method of claim 11 wherein the energy removal film is removed from the first cavity by a thermal process.

13. The method of claim 12 further comprising:
exposing the energy removal film to electromagnetic energy in association with the thermal process.

14. The method of claim 10 wherein the metallization level includes a third metallization structure and a second cavity arranged between the second metallization structure and the third metallization structure, and the dielectric layer is further deposited inside the second cavity to encapsulate a second air gap.

15. The method of claim 14 wherein the first metallization structure is spaced from the second metallization structure by a first spacing, and the second metallization structure is spaced from the third metallization structure by a second spacing less than the first spacing.

16. The method of claim 15 wherein the second spacing is selected with a dimension that provides pinch off of the dielectric layer at an entrance to the second cavity.

17. The method of claim 10 wherein the first metallization structure and the second metallization structure have a parallel arrangement, and the first metallization structure and the second metallization structure are composed of a conductor.

18. The method of claim 10 wherein the cap layer is composed of a porous dielectric material.

19. (canceled)

20. The method of claim 10 wherein the surfaces surrounding the first cavity include a first liner layer at a sidewall of the first metallization structure and a second liner layer at a sidewall of the second metallization structure.

21. The interconnect structure of claim 1 wherein the metallization level further includes an intralayer dielectric layer, a third metallization structure in the intralayer dielectric layer, and a fourth metallization structure in the intralayer dielectric layer, and the dielectric layer and the cap layer are arranged over the third metallization structure, the fourth metallization structure, and a portion of the intralayer dielectric layer between the third metallization structure and the fourth metallization structure.

22. The method of claim 10 wherein the metallization level further includes a third metallization structure formed in the intralayer dielectric layer, and a fourth metallization structure formed in the intralayer dielectric layer, and the dielectric layer and the cap layer are further deposited over the third metallization structure, the fourth metallization structure, and a portion of the intralayer dielectric layer between the third metallization structure and the fourth metallization structure.
